(19) United States
(12) Patent Application Publication
(10) Pub. No.: US 2009/0144970 A1
(43) Pub. Date: Jun. 11, 2009

(54) FABRICATING AN ARRAY OF MEMS PARTS ON A SUBSTRATE

(75) Inventors: Tseng-Yang Hsu, San Marino, CA (US); Chih-Hsiang Lai, Taipei City (TW)

Correspondence Address: BLAKELY SOKOLOFF TAYLOR & ZAFMAN LLP, 1279 OAKMEAD PARKWAY, SUNNYVALE, CA, 94085-4040, US

(73) Assignee: WinMEMS Technologies Holdings Co., Ltd.

(21) Appl. No.: 11/951,772

(22) Filed: Dec. 6, 2007

(51) Int. Cl. H01L 21/00; H05K 3/00; H05K 3/30; B23G 1/22

(52) U.S. Cl. 29/832; 29/846; 324/754; 257/774; 408/107

(57) ABSTRACT

A method for fabricating a micro-electro-mechanical system (MEMS) device. The method comprises fabricating a MEMS part on a substrate, and detaching the MEMS part from the substrate. After detaching the MEMS part from the substrate, attaching the MEMS part to an application platform.

### FIELD OF THE INVENTION

At least one embodiment of the present invention pertains to a Micro-Electro-Mechanical System (MEMS), and more particularly, to fabrication of MEMS parts on a substrate and integration of the MEMS parts onto an application platform.

### BACKGROUND

Micro-Electro-Mechanical Systems (MEMS) is the integration of mechanical elements, sensors, actuators, and electronics on a common substrate, such as a silicon substrate, through microfabrication technology. While the electronics are fabricated using integrated circuit (IC) process sequences (e.g., CMOS, Bipolar, or BICMOS processes), the micromechanical components are fabricated using compatible “micromachining” processes that selectively etch away parts of the silicon wafer or add new structural layers to form the mechanical and electromechanical devices.

MEMS technology is based on a number of tools and methodologies, which are used to form small structures with dimensions in the micrometer scale (one millionth of a meter). Significant parts of the technology have been adopted from integrated circuit (IC) technology. For instance, similar to ICs, MEMS structures are, in general, realized in thin films of materials and patterned with photolithographic methods. Moreover, similar to ICs, MEMS structures are, in general, fabricated on a wafer by a sequence of deposition, lithography and etching.

With the increasing complexity of MEMS structures, the fabrication process of a MEMS device also becomes increasingly complex. Conventionally, a MEMS structure comprising a large number of MEMS parts with multiple vertical layers deep (e.g., a MEMS probe card) is built on a single substrate, using a sequence of deposition steps across an entire wafer. A concern with the conventional methodology is that a defect or contamination occurring in any deposition step and in any individual MEMS part may cause the entire wafer to fail. Thus, there is a need to improve the conventional fabrication process in order to increase the yield of MEMS devices and reduce the cycle time and costs.

### BRIEF DESCRIPTION OF THE DRAWINGS

One or more embodiments of the present invention are illustrated by way of example and not limitation in the figures of the accompanying drawings, in which like references indicate similar elements and in which:

FIG. 1 is a flowchart illustrating a process of fabricating a Micro-Electro-Mechanical System (MEMS) device according to one embodiment of the invention.

FIGS. 2A-2E illustrate a cross-section view of a process of fabricating a MEMS part on a reusable substrate according to one embodiment of the invention.

FIGS. 3A-3E illustrate a prospective view of the process of FIGS. 2A-2E.

FIG. 4 illustrates an embodiment of a MEMS part attached to an application platform.

### DETAILED DESCRIPTION

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention.

A method for fabricating a Micro-Electro-Mechanical System (MEMS) part and an apparatus comprising the MEMS part are described. In one embodiment, an array of MEMS parts is fabricated on a substrate. The MEMS parts are individually detached (“picked”) from the substrate, and then attached (“placed”) to an application platform in an unpackaged state using die attachment techniques. This “pick-and-place” technique greatly increases the flexibility with respect to how the MEMS parts are fabricated and used. For example, the array of MEMS parts may be detached from the substrate concurrently, or one or more parts at a time. Each of the MEMS parts may be attached to the same or different application platforms. Further, the MEMS parts attached to the same application platform may be fabricated on the substrate in a first arrangement and then attached to the application platform in a second arrangement, where the first arrangement and the second arrangement may have different spacing between the MEMS parts, different orientations of the MEM parts, or a combination of both.

The term “MEMS part” herein refers to a sub-structure (e.g., a mechanical part, an optical part, an electrical part, or the like) of a micro-machine, a micro-machining processed structure, or a MEMS processed structure. Typically, a MEMS part has dimensions ranging from 10×10×10 μm to 5000×5000×5000 μm. Examples of a MEMS part include a probe in an array of probes, which can be arranged on an application platform to form a probe card. A probe card uses the probes to establish an electrical path between an electronic test system and a wafer for testing and validation of the wafer. Other examples of a MEMS part include an optical laser module, optical lenses, micro-gears, micro-resistors, micro-capacitors, micro-inductors, micro-diaphragms, micro-relays, micro-springs, waveguides, micro-grooves, and the like.

One feature of the technique described herein is that the MEMS parts on the application platform, which is used in the final application, are fabricated on a substrate different and separate from the application platform. The term “substrate” herein refers to the substrate used only in the fabrication process without involvement in the operations of the MEMS parts and the final MEMS device incorporating the MEMS parts. Examples of a substrate for fabricating a MEMS part include, but are not limited to, ceramics, glasses, metal plates, plastic plates, and semiconductor wafers. A non-silicon substrate, compared to a Si-based substrate, offers a larger number of standard sizes and is available as a thicker and non-circular standard substrate. Further, a non-silicon substrate is inert to most chemicals used during fabrication processes. Most substrates, including Si-based substrate, can be processed with the MEMS parts thereon. Processed materials on the substrates can be later removed or dissolved without damaging the substrates. Therefore, the substrate for fabricating MEMS parts, as described herein, is a “reusable substrate,” unless otherwise indicated. A reusable substrate can be reused for a next batch of MEMS part fabrication after the MEMS parts are detached therefrom and residual substances are removed.

The term “application platform” herein refers to a platform (e.g., a substrate) used in operation as part of an operational MEMS device (e.g., a probe card, a laser module, etc.). An application platform may comprise, but is not limited to, semiconductor, glass, ceramics, low-temperature co-fired ceramics (LTCC), high-temperature co-fired ceramics (HTCC), metal, dielectric materials, organic materials, or any combinations of the above, that are suitable for the attachment of a MEMS part and for the final application purposes. An application platform has components fabricated thereon for specific application purposes. The components include, but are not limited to, electrical connection, electrical contact, electrical isolation, electrical grounding, integrated circuit (IC) module, application specific IC (ASIC) module, dielectric patterning, conducting opening definition, mechanical support, mechanical protection, thermal conduction, electrostatic discharge (ESD) protection, confinement for parts, and wire bonding pads. One or more MEMS parts are to be attached to this application platform to complete the integration of a MEMS device. It is understood that an application platform may include one or more MEMS parts fabricated on one or more reusable substrates. The MEMS parts attached to an application platform may be of different orientations, shapes, sizes and materials, and may have different functions.

According to embodiments of the present invention, MEMS parts are fabricated on a substrate different from the substrate used for the final application. Thus, yield of the individual MEMS parts does not directly affect the yield of the final product that integrates one or more of the MEMS parts. A selection process of acceptable MEMS parts may be performed before the MEMS parts are attached to the application platform. Defective MEMS parts may be discarded before the attachment process or left on the reusable substrate.

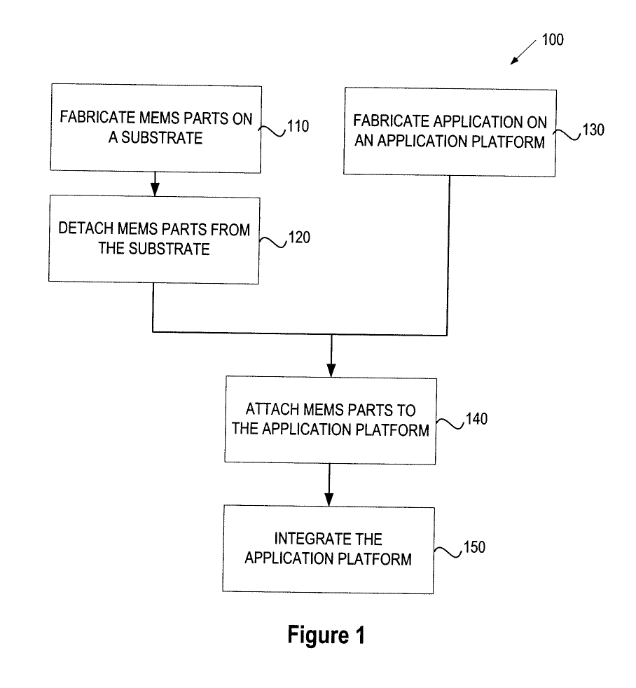

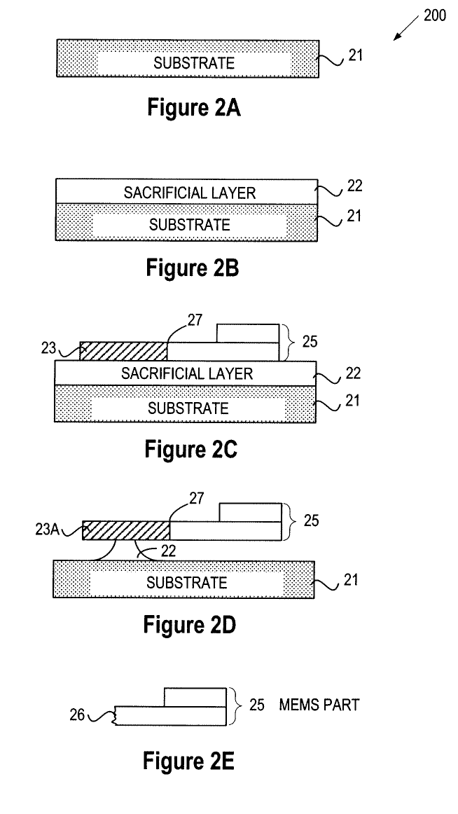

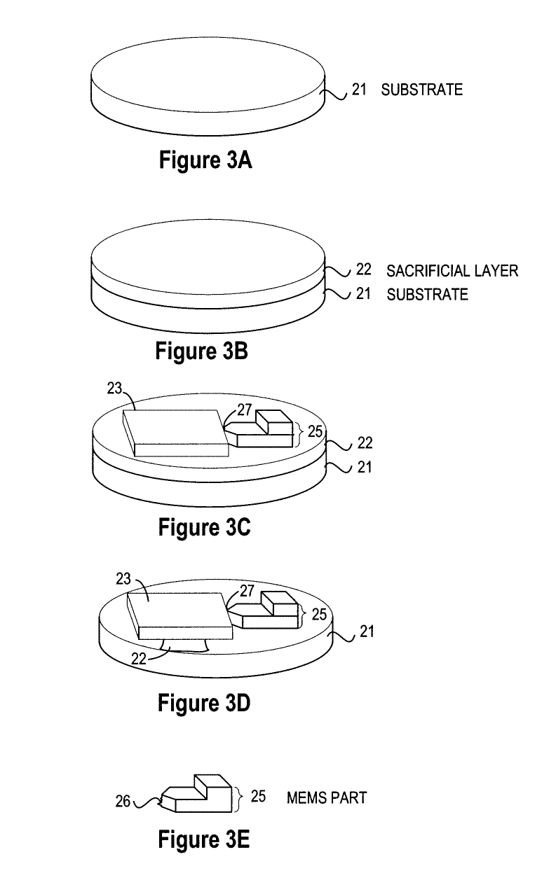

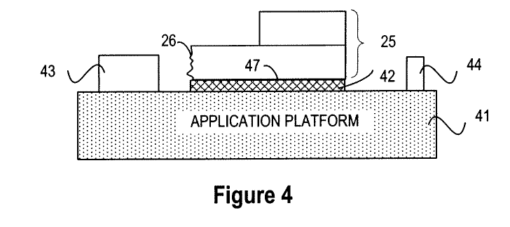

FIG. 1 is a flowchart illustrating an overview of a process 100 for fabricating MEMS parts and forming a MEMS device according to an embodiment of the present invention. At block 110, MEMS parts are fabricated on a substrate. At block 120, MEMS parts are detached from the substrate. The fabrication and detachment of the MEMS parts will be described in greater detail with reference to FIGS. 2 and 3. At block 130, an application platform is fabricated to form necessary components thereon, if any, such as electronic components, electrical components, and mechanical components, as described above. The preparation of the application platform may occur in parallel with the fabrication and detachment of the MEMS parts or before or after the fabrication and/or detachment of the MEMS parts. At block 140, one or more of the detached MEMS parts are attached to the application platform, one or more parts at a time, with a machine. The attachment of the MEMS parts to the application platform will be described in greater detail with reference to FIG. 4. At block 150, final processing steps are performed to integrate the components on the application platform to complete the MEMS device designed for specific application purposes. The final processing steps may also include integration with modules external to the application platform to enable the functionality of the application platform. Suitable external modules include, but are not limited to, an electronic module, a power supply, and/or a printed circuit board (PCB) that comprises circuit elements, such as capacitors, resistors, inductors, and integrated circuit components. In the scenario of probe card fabrication, integration with a PCB may include coupling the PCB with the application platform (with MEMS parts attached thereon) using a mechanical assembly.

The technique described herein may be useful for a variety of products that include one or more MEMS parts. Illustratively, the final products may include a laser module in which a laser source (a MEMS part) is integrated and aligned with one or more lenses (which may also be MEMS parts). In this scenario, the substrate to which the laser module is bonded is the application platform. The attachment process of the laser module can be performed using die attachment techniques, e.g., the technique of bonding a die to a substrate commonly used in semiconductor industry. The application platform may have been patterned to form electrical connections among the components thereon and to a system external to the application platform. In another scenario, the final products may include a probe card including a plurality of MEMS probes. The location of the probes on the probe card may be customized. Fabricating the probes on the probe card substrate (i.e., the application platform) generally involves a sequence of processing steps. Conventionally, a defect developed during any processing step in any of the probes may render the entire probe card unusable. Using the techniques described herein, the probes may be fabricated on a separate substrate, and only the good probes are selected and attached to the probe card substrate. The probe card substrate may be patterned to electrically connect each of the probes to an external printed circuit board for transmitting probe signals.

Referring to FIGS. 2A-2E and FIGS. 3A-3E, an embodiment of a process 200 for fabricating a MEMS part on a reusable substrate 21 is described. FIGS. 2A-2E illustrate a cross-section view of process 200, and FIGS. 3A-3E illustrate a corresponding perspective view. Although only one MEMS part is shown in the figures, it is understood that the same process can be applied to the fabrication of an array of MEMS parts on a wafer simultaneously. It is appreciated that the array of MEMS parts may include identical MEMS parts or different MEMS parts. It is also appreciated that MEMS parts fabricated by completely or partially different sequences of processing operations can also be formed on reusable substrate 21. FIGS. 2A and 3A show reusable substrate 21. FIGS. 2B and 3B show a sacrificial layer 22 formed on reusable substrate 21. Sacrificial layer 22 may be made of for example, a conductive material (such as copper) deposited on reusable substrate 21 by electrical forming (plating) techniques. In FIGS. 2C and 3C, sections 23 and 25 are formed on sacrificial layer 22. Section 23 illustratively represents the portion where an anchoring structure, referred to as an island, is to be formed. Section 25 illustratively represents the portion where a MEMS part 25 is to be formed. A person or ordinary skill in the art will appreciate that different MEMS parts may be formed by different number of layers (two layers to make up MEMS part 25 are shown illustratively) with different dimensions. In one embodiment, sections 23 and 25 may be formed at the same time in a defined mold that is formed by photolithographic techniques. For example, one or more photoresists may be used to define boundaries or openings for sections 23 and 25 in one or more processing operations. Then, the sections 23 and 25 may be formed of materials suitable for the purpose of the MEMS part to be formed, e.g., openings defining sections 23 and 25 may be filled with metal by metal plating. After the photoresist(s) is stripped, island 23 and MEMS part 25, as well as an anchor point 27 adjoining the two sections, are formed.

Island 23 provides support to one or more adjacent MEMS part 25 (only one is shown in FIG. 2D), when, at a later processing operation (as shown in FIG. 2E), sacrificial layer 22 is removed. In some embodiments, the anchor point 27 may be shaped (e.g., thinned or narrowed) to form a tip (as shown in FIG. 3C) to facilitate the detachment of the MEMS part 25 from the island 23. The shape of the anchor point 27 may be defined (e.g., using photolithographic techniques) at the same time when sections 23 and 25 are formed in FIGS. 2C and 3C, or at a later processing operation (e.g., a subsequent etching operation).

After the formation of MEMS part 25, further processing operations (not shown) may be performed to pattern the MEMS part 25 into a final structure.

In FIGS. 2D and 3D, the sacrificial layer 22 is removed from underneath the MEMS part 25 by, for example, an etching operation. The choice of the etchant depends on the material of the sacrificial layer 22. For example, the etchant may be an acid copper etchant (e.g., a combination of acetic acid, hydrogen peroxide, and deionized water) for a copper-based sacrificial layer. As another example, if photoresist is used as the material for the sacrificial layer 22, the etchant may be a photoresist stripper or acetone. In one embodiment, a surface area of island 23 is greater than that of MEMS part 25, e.g., with a ratio of 10:1. The surface area ratio necessary for the processing operations described herein may depend on the relative shapes of island 23 and MEMS part 25. For example, the surface area ratio may be greatly reduced to 5:1, 2:1 or less if island 23 has a substantially round shape and MEMS part 25 has a long and narrow shape. The surface area ratio may increase if both island 23 and MEMS part 25 have a substantially round or square shape. As the surface area of island 23 is greater than that of MEMS part 25 (as shown in FIGS. 3C and 3D), sacrificial layer 22 underneath MEMS part 25 is etched faster than sacrificial layer 22 underneath island 23. When sacrificial layer 22 is completely removed from underneath the MEMS part 25, there remains a substantial amount of sacrificial layer 22 underneath island 23 to hold the island 23 on reusable substrate 21. At this point, MEMS part 25 is held in place by island 23 only.

In FIG. 2E, external force is applied to detach the MEMS part 25 from the island 23. The external force may be applied at or near the anchor point 27, laterally or vertically with respect to the surface of reusable substrate 21. The external force may be applied by a tool operated manually or by a machine. The external force physically breaks the narrow or thin connection (the tip) at anchoring point 27. After the notch is broken, a “broken” surface 26 is formed on the side of MEMS part 25 that was previously connected to island 23. Broken surface 26 is distinguishable from a surface defined by conventional methods of surface formation, such as patterned photoresist. In general, a surface formed by patterned photoresist is smooth and regularly shaped. A surface formed by forcibly breaking (such as broken surface 26) is generally rough and substantially irregular. A person of ordinary skill in the art would be able recognize this “signature” represented by broken surface 26 by examining the smoothness and shape of the surface. In a scenario where MEMS part 25 is made of metal (such as a metal probe), the roughness and irregularity of a broken metal surface is visually discernable and distinguishable from a plated metal surface defined by photoresist or other sacrificial materials.

In an alternative embodiment, instead of etching sacrificial layer 22, a Si-based substrate may replace reusable substrate 21 described above and selectively etched to a depth enough to free MEMS part 25. In this alternative embodiment, MEMS part 25 and the island 23 may be formed directly on top of the Si-based substrate. After formation, the Si-based substrate is then etched away from underneath MEMS part 25 such that there is no direct contact between MEMS part 25 and the substrate. A substantial amount of the Si-based substrate underneath island 23 remains to keep island 23 and MEMS part 25 in place. Thereafter, MEMS part 25 can be detached from island 23 in the same manner as described in the embodiment of FIG. 2A-2E.

One notable feature of process 200 is that MEMS part 25 is detached from reusable substrate 21 in a highly controlled manner by the use of island 23 as an anchoring structure. Island 23 ensures that MEMS part 25 stays at a fixed location after the removal of sacrificial layer 22 from underneath MEMS part 25. When hundreds or thousands of MEMS parts are fabricated concurrently on a reusable substrate, the use of islands minimizes the possibility that these MEMS parts can be randomly scattered all over the reusable substrate after sacrificial layer 22 is removed. Scattered MEMS parts would be difficult to pick up and susceptible to damage.

In one embodiment, a MEMS part may be manually picked up by a tool (e.g., a pair of tweezers) suitable for a specific MEMS part. In another embodiment, a MEMS part may be picked up by a machine, such as a die attach machine with a custom-made pick-up arm to pick up a MEMS part from a target location on the substrate. A die attach machine is commonly used for picking up a die from as well as bonding the die to a substrate with high precision.

FIG. 4 shows MEMS part 25 attached to an application platform 41. Although only one MEMS part 25 is shown in the figure, it is understood that the same application platform 41 may have a plurality of MEMS parts attached thereto, which may have different sizes, functions, orientations, or materials. MEMS part 25 includes a bonding surface 47 for attachment to application platform 41, and broken surface 26 formed by detaching MEMS part 25 with force from a substrate (e.g., reusable substrate 21) on which MEMS part 25 was fabricated. It is also worth noting that the term “attachment” herein refers to the formation of direct or indirect contact between two elements. Thus, attaching MEMS part 25 to application platform 41 may involve directly placing MEMS part 25 on top of application platform 41 (as shown), or placing MEMS part 25 on one or more components that are fabricated on application platform 41. In one embodiment, application platform 41 has components 43, 44 fabricated thereon before the attachment of MEMS part 25. Components 43, 44 comprise at least one of the following: an electrical component, an optical component, an electronic component, or a mechanical component.

In one embodiment, the adhesion of the MEMS part 25 to application platform 41 may be accomplished by a die attachment technique, such as applying a bonding material 42 between the MEMS part 25 and application platform 41 (or a component on the application platform). To improve the adhesion, the MEMS part 25 and application platform 41 can be patterned with cavities and protrusions. The type of bonding material 42 includes, but is not limited to, epoxy, glue, paste, cement, silicone, conductive adhesive, eutectic metal, and any combination of the above. Some bonding material 42, e.g., eutectic metal and solder, may be in the form of a template or a coupon. Bonding material 42 can be applied to, or formed on, application platform 41 and/or the bonding surface of MEMS part 25 manually, or by a machine or equipment. Bonding material 42 may be applied or formed by electrical forming, thin film deposition, spin patterning, spray patterning, laminating, chemical forming, soldering, thermal compression, chemical join, thermal laminating, dispensing, mechanical locking or any combination of the above.

After the formation of bonding material 42, MEMS part 25 may be attached to application platform 41 by a machine with custom-made parts using any of the die attachment techniques described above. It is to be noted that the die attachment techniques described herein are applied to a MEMS part and an application platform, instead of a die and a PCB. Unlike a die residing in a package, a MEMS part is not packaged and may have any three-dimensional shape.

Typically, a MEMS part (e.g., MEMS part 25) has dimensions ranging from 10×10×10 μm to 5000×5000×5000 μm. A machine with custom-made parts is able to pick up, orient, align and attach the MEMS part to a specific location of an application platform with desired precision and orientation. Examples of such a machine include a die-attach machine, a pick-and-place machine, and a flip-chip machine, all of which are commercially available and can be operated manually, semi-automatically, or automatically. Typically, the pick-up head or arm of the machine can be custom made to pick up a MEMS part of a specific size and shape. Generally, a MEMS part with the dimensions described above may be picked up by vacuum, mechanical grabbing, mechanical locking, magnetic force, or any suitable methods. The machine that performs the attachment may be the same machine or a different machine that detaches the MEMS part from the reusable substrate.

Moreover, the adhesion of the MEMS part to the application platform may be enforced by local heating and/or pressure. The adhesion may be further enforced by local chemical application, or special local environments (such as forming gas or flux). Depending on the machine type and the degree of automation, the time it takes to attach a MEMS part can be as short as seconds. More than one MEMS part can be attached at a time. For example, a die-attach machine may be configured to pick up one or more MEMS parts and attach them to the specific locations on the application platform.

In some embodiments, after the attachment process, a MEMS part can be detached from its application platform for repair or replacement purposes. In an embodiment where a solder is used to join the MEMS part to the application platform, an attached MEMS part may be detached from the application platform by applying local heating above the solder melting point to the joining spot. An attached MEMS part may be detached from the application platform manually or by a machine. The machine may be the same machine as the one performing the attachment, or a different machine.

After the attachment of the MEMS part and subsequent integration process (e.g., integration with a PCB as described at block 150 of FIG. 1), at this point, the MEMS part and other components on the application platform form a MEMS device, which is operationally for specific application purposes.

Thus, a method and apparatus for fabricating MEMS parts on a reusable piece have been described. It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense.

1. A method comprising:
fabricating a micro-electro-mechanical system (MEMS) part on a substrate, the MEMS part being connected to a structure on the substrate at an anchor point;
detaching the MEMS part from the structure at or near the anchor point with force to remove the MEMS part from the substrate; and
after removing the MEMS part from the substrate, attaching the MEMS part to an application platform.

2. The method as recited in claim 1, further comprising:
fabricating an array of MEMS parts in a first arrangement, and
attaching the one or more MEMS parts to the application platform in a second arrangement, wherein the first arrangement and the second arrangement have different spacing between the array of MEMS parts, different orientations of the array of MEMS parts, or a combination of both.

3. The method as recited in claim 1, wherein the MEMS part are a probe of a probe card.

4. The method as recited in claim 1, wherein detaching the MEMS part further comprises:
removing a sacrificial layer underneath the MEMS part while retaining the sacrificial layer between an anchoring structure of the MEMS part and the substrate.

5. The method as recited in claim 1, wherein detaching the MEMS part further comprises:
removing a first portion of the substrate underneath the MEMS part while retaining a second portion of the substrate underneath the structure.

6. The method as recited in claim 1, wherein detaching the MEMS part further comprises:
shaping a tip of the anchor point between the MEMS part and the structure to facility the detaching of the MEMS part.

7. The method as recited in claim 1, wherein detaching the MEMS part further comprises:
obtaining MEMS part that are unconnected to each other after detaching the MEMS part from the substrate.

8. The method as recited in claim 1, wherein attaching the MEMS part further comprises:
using a machine to pick up, align, orient, and attach the MEMS part to a predetermined location on the application platform.

9. The method as recited in claim 1, wherein attaching the MEMS part further comprises:
fabricating the application platform to form components thereon prior to attaching the MEMS part, the components on the application platform including at least one of the following: an electrical component, an optical component, an electronic component, or a mechanical component.

10. A method comprising:
forming a sacrificial layer on a substrate;
forming an island connecting to a micro-electro-mechanical system (MEMS) part on the sacrificial layer;
removing the sacrificial layer except a portion of the sacrificial layer located between the island and the substrate;
detaching the MEMS part from the substrate; and
after detaching the MEMS part from the substrate, attaching the MEMS part to an application platform.

11. The method as recited in claim 10, wherein detaching the MEMS part from the substrate further comprises:
detaching the MEMS part from the island, the island remaining attached to the substrate by the sacrificial layer after the removal of the sacrificial layer.

12. The method as recited in claim 10, wherein the island has a larger surface area than the surface area of the MEMS part.

13. The method as recited in claim 10, wherein detaching the MEMS part from the substrate further comprises:
detaching, by force, the MEMS part from the island at or near an anchor point connecting the MEMS part to the island.

14. The method as recited in claim 10, further comprising:
shaping a tip of a connection between the MEMS part and the island to facility the detaching of the MEMS part.

15. The method as recited in claim 10, further comprising:
using a machine to pick up, align, orient, and attach the MEMS part to a predetermined location on the application platform.

16. An apparatus comprising:
an application platform; and
a micro-electro-mechanical system (MEMS) part on the application platform, the MEMS part having a broken surface formed by detaching the MEMS part with force from a substrate on which the MEMS part was fabricated, and a bonding surface to attach to the application platform.

17. The apparatus as recited in claim 16, further comprising:
a component coupled to the MEMS part on the application platform, the component fabricated on the application platform and comprising at least one of the following: an electrical component, an optical component, an electronic component, or a mechanical component.

18. The apparatus as recited in claim 16, wherein the MEMS part is attached to the application platform with a bonding material using die attachment techniques.

19. The apparatus as recited in claim 16, further comprising:
a second MEMS part on the application platform, the second MEMS part and the MEMS part having different orientations, the second MEMS part having a second broken surface formed by detaching the second MEMS part with force from the substrate on which the second MEMS part was fabricated.

20. The apparatus of as recited in claim 16, wherein the MEMS part is attached to the application platform as an unpackaged part.
